(19) United States
(12) Patent Application Publication
(10) Pub. No.: US 2010/0227480 A1
(43) Pub. Date: Sep. 9, 2010

(54) APPARATUS AND METHOD FOR MAINTAINING A NEAR-ATMOSPHERIC PRESSURE INSIDE A PROCESS CHAMBER

(75) Inventor: Antonius Marinus Coenraad Petrus Van De Kerkhof, Handel (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/993,312

(22) PCT Filed: Jun. 23, 2006
(86) PCT No.: PCT/IB06/52059

§ 371 Date: May 12, 2010

(30) Foreign Application Priority Data
Jun. 29, 2005 (EP) 05105814.7

(51) Int. Cl. H01L 21/477

(52) U.S. Cl. 438/795; 237/2 A

(57) ABSTRACT

A process chamber (1) is provided for a thermal treatment of a semiconductor wafer. The process chamber (1) comprises a gas injection line (4), for injecting a process gas into the process chamber (1), and a gas exhaustion line (14). A pump (8) is coupled to the gas exhaustion line (14) and maintains a pressure inside the process chamber (1) at a level that is higher than the ambient atmospheric pressure outside the process chamber (1).

This invention relates to an apparatus and a method for maintaining a near-atmospheric pressure inside a process chamber.

In US 2004/0255860 a rapid thermal processing apparatus is disclosed comprising a process chamber coupled to a gas exhaustion line, a pressure adjustment valve for adjusting the pressure inside the process chamber and a pump for pumping gas out of the process chamber. The process chamber further comprises a gas injection line for injecting process gas into the process chamber. The pressure adjustment valve adjusts the pressure inside the process chamber such that the pressure inside the process chamber is maintained at an appropriate level, which is higher than atmospheric pressure (i.e. a range of about 760˜800 Torr). It appears that a variation of the atmospheric pressure conditions may induce a situation in which the pressure adjustment valve cannot adjust the pressure inside the process chamber to the appropriate value, as a result of which the process running in the process chamber has to be aborted.

It is an object of the invention to provide an apparatus and a method which maintains a pressure inside the process chamber higher than the ambient atmospheric pressure outside the process chamber and which is less sensitive of the atmospheric pressure conditions. According to the invention, this object is achieved by providing a system as claimed in claim 1.

A process chamber is provided with a gas injection line for injecting a process gas into the process chamber. The pressure inside the process chamber should be higher than the ambient atmospheric pressure outside the process chamber to provide the appropriate processing conditions for the process chamber and to avoid ambient gas leaking into the process chamber. For this purpose a pump is provided, which is arranged to remove gas out of the process chamber and which maintains the pressure inside the process chamber at an appropriate level. The pump is less sensitive to fluctuations of the ambient atmospheric pressure, and hence the stability of the processing conditions is improved.

In a first embodiment a control system is provided which is able to adjust the pumping speed of the pump dependant on the pressure inside the process chamber and the ambient atmospheric pressure outside the process chamber, thereby further improving the stability of the processing conditions.

In a second embodiment the pump comprises an outlet, which is connected to a blower.

In a third embodiment the pump is connected to the process chamber via a pressure adjustment valve, thereby introducing an additional pressure regulator and reducing the interaction between the pump and the process chamber, because the pressure adjustment valve serves as a bather against gas or any other unwanted material, which may flow from the pump backwards into the direction of the process chamber.

A processing method is provided to maintain a pressure inside a process chamber, which is provided with a gas injection line for injecting a gas into the process chamber, at an appropriate level, which is higher than the ambient atmospheric pressure outside the process chamber. The method includes pumping gas out of the process chamber with a pump, which maintains the pressure inside a process chamber at an appropriate level.

These and other aspects of the invention will be further elucidated and described with reference to the drawings, in which:

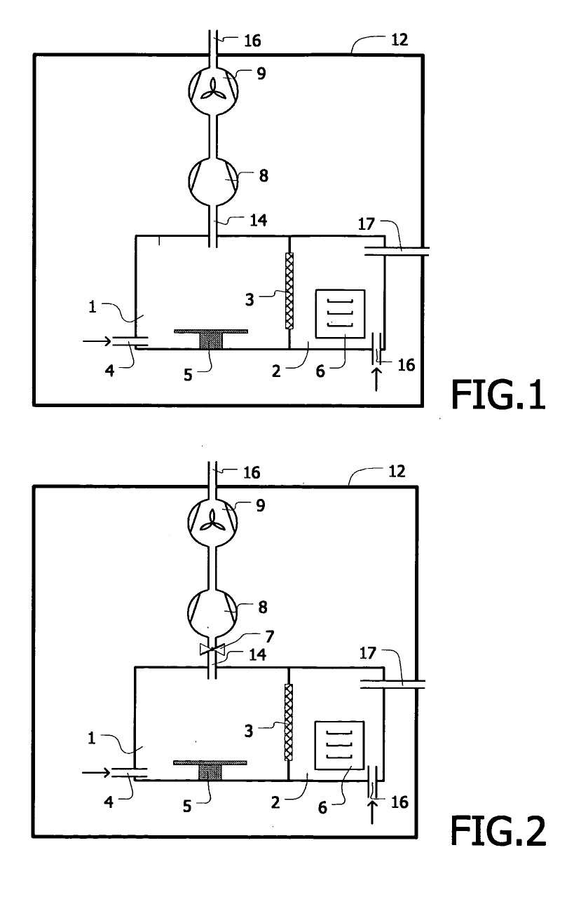

FIGS. 1-3 illustrate cross-sectional views of various embodiments of the invention.

The Figures are not drawn to scale. In general, identical components are denoted by the same reference numerals in the Figures.

As is illustrated in FIG. 1, a clean room chamber 12 comprises a process chamber 1 which adjoins a load chamber 2. The process chamber 1 is provided with a holder 5 for a semiconductor wafer, a gas exhaustion line 14 for exhausting gas to an outside environment, which has atmospheric pressure conditions, via a blower 9, and a gas injection line 4 for injecting process gas into the process chamber 1. The load chamber 2 is provided with a cassette 6, which holds the semiconductor wafers, a further gas exhaustion line 17 and a further gas injection line 16. The further gas exhaustion line 17 may also be coupled to devices, such as a further pressure adjustment valve or a further pump, which provide a proper functioning of the gas exhaustion line. The further gas exhaustion line 17 and the further gas injection line 16 are arranged to set the appropriate conditions inside the load chamber 2, such as pressure, which may be comparable to the conditions that are required in the process chamber 1. Further, also a plurality of process chambers 1 may be provided, that all adjoin the load chamber 2. The load chamber 2 and the process chamber 1 are separated by a shutter 3 which opens when the semiconductor wafer is loaded from the load chamber 2 into the process chamber 1 on the holder 5, and also opens if the semiconductor wafer is loaded from the holder 5 into the load chamber 2. The loading of the semiconductor wafer is executed with a loading device which is not shown in FIG. 1.

In the process chamber 1 the semiconductor wafer is subjected to a thermal treatment, in this case for example rapid thermal processing (RTP). RTP is able to achieve a high temperature in a short processing time, which is in the order of a few seconds to a few minutes, which is beneficial for minimizing impurity diffusion into the semiconductor wafer.

The pressure inside the process chamber 1 should have a value that assures the optimum process conditions for RTP. As is generally known, any oxygen present in the process chamber 1 during the RTP treatment of the semiconductor wafer will have a negative effect on the performance of devices that are formed in the semiconductor wafer. For this purpose the process gas, which is injected into the process chamber 1, does not comprise oxygen. Furthermore, the pressure inside the process chamber is higher than the pressure in the clean room chamber 12, which is the ambient atmospheric pressure of the process chamber 1. In this way it is prevented that gas, and especially oxygen, from the clean room chamber 12 enters the process chamber 1. The appropriate level of the pressure inside the process chamber is in a range of about 740˜800 Torr, and the pressure inside the clean room chamber 12 is normally about 20 Torr lower than the pressure inside the process chamber 1. To maintain the pressure inside the process chamber 1 at a level that is higher than the pressure inside the clean room chamber 12, a pump 8 is coupled to the gas exhaustion line 14 and the blower 9. The pump 8 has such a pumping speed that the pressure inside the process chamber 1, in combination with the injection of the process gas into the process chamber 1 via the gas injection line 4, is maintained at a level that is higher than the pressure inside the clean room chamber 12. By placing the pump 8, instead of a pressure adjustment valve, between the gas exhaustion line 14 and the blower 9, the pressure inside the process chamber 1 is less sensitive to a variation of the atmospheric pressure, which influences both the pressure inside the clean room chamber 12 and the pressure of the outside environment. When a pressure adjustment valve would be used instead of the pump 8, as in the prior art, the pressure inside the process chamber 1 would be far more sensitive to variations of the atmospheric pressure, which could lead to unwanted process conditions inside the process chamber 1 and ultimately to an abort of the process.

A further improvement is illustrated in FIG. 2, in which a pressure adjustment valve 7 is coupled to the pump 8 and the gas exhaustion line 14. The pressure adjustment valve 7 functions as an additional pressure regulator for the pressure inside the process chamber 1. Furthermore, the pressure adjustment valve 7 shields the process chamber 1 from gas, or any other unwanted material, that may escape from the pump 8 and subsequently may enter the process chamber 1. In this way the pressure adjustment valve 7 provides a reduced interaction between the pump 8 and the process chamber 1.

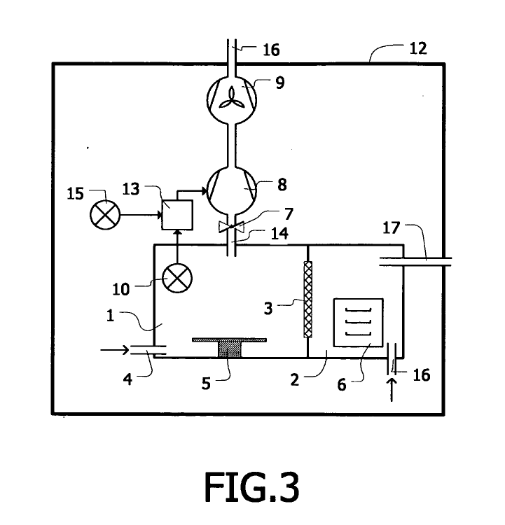

Another embodiment is illustrated in FIG. 3, in which a control system 13 is provided, which controls the pumping speed of the pump 8 dependant on the pressure inside the process chamber 1 and the ambient atmospheric pressure of the process chamber 1, which is the pressure inside the clean room chamber 12. The pressure inside the process chamber 1 is measured with a pressure measurement device 10 and is a first input parameter for the control system 13. The pressure inside the clean room chamber 12 is measured with a further pressure measurement device 15, and this pressure is a second input parameter for the control system 13. Additionally the atmospheric pressure of the outside environment may be used as a third input parameter for the control system 13, which is not shown in FIG. 3. Based on the values of the input parameters the control system 13 sets the pumping speed of the pump 8 such that the appropriate pressure is set inside the process chamber 1.

In summary, a process chamber is provided for a thermal treatment of a semiconductor wafer. The process chamber comprises a gas injection line, for injecting a process gas into the process chamber, and a gas exhaustion line. A pump is coupled to the gas exhaustion line and maintains a pressure inside the process chamber at a level that is higher than the ambient atmospheric pressure outside the process chamber.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. An apparatus comprising a process chamber and a pump arranged to remove gas from the process chamber, the process chamber being provided with a gas injection line for injecting a gas into the process chamber, characterized in that said pump is arranged to maintain a pressure inside the process chamber that is higher than the ambient atmospheric pressure outside the process chamber;

2. An apparatus as claimed in claim 1, further comprising a control system arranged to adjust the speed of the pump dependant on the pressure inside the process chamber and the ambient atmospheric pressure outside the process chamber.

3. An apparatus as claimed in claim 1, wherein the pump comprises an outlet, which is connected to a blower.

4. An apparatus as claimed in claim 1, wherein the pump is connected to the process chamber via a pressure adjustment valve. .

5. A processing method in which a pump, which is arranged to remove gas from the process chamber, maintains a pressure inside a process chamber, which is provided with a gas injection line for injecting a gas into the process chamber, that is higher than the ambient atmospheric pressure outside the process chamber.

6. The processing method as claimed in claim 5, further comprising adjusting the speed of the pump dependant on the pressure inside the process chamber and the ambient atmospheric pressure outside the process chamber by means of a control system.
